(19) United States
(12) Patent Application Publication
(10) Pub. No.: US 2024/0258447 A1
(43) Pub. Date: Aug. 1, 2024

(54) DIFFUSED B-Ga2O3 PHOTOCONDUCTIVE DEVICES

(71) Applicants: Lawrence Livermore National Security, LLC, Livermore, CA (US); Washington State University, Pullman, WA (US)

(72) Inventors: Clint Frye, Oakland, CA (US); Sara E. Harrison, Livermore, CA (US); Joel Basile Varley, San Francisco, CA (US); Lars F. Voss, Livermore, CA (US); Jani Jesenovec, Pullman, WA (US); Benjamin Dutton, Pullman, WA (US); Dylan Evans, Livermore, CA (US); John S. McCloy, Pullman, WA (US)

(21) Appl. No.: 18/426,083

(22) Filed: Jan. 29, 2024

Related U.S. Application Data
(60) Provisional application No. 63/482,422, filed on Jan. 31, 2023.

(51) Int. Cl. H01L 31/032; G02F 1/1333; H01L 31/18

(52) U.S. Cl. CPC H01L 31/0321; G02F 1/133362; H01L 31/18

(57) ABSTRACT

Various devices, systems and methods such as photonductive semiconductor switches (PCSS) and optically addressable light valves (OALVs) include a photoconducting β-Ga₂O₃ layer having a transition metal (TM) doped region formed by diffusion of transition metal into a β-Ga₂O₃ substrate. The diffusion of the TM into the β-Ga₂O₃ substrate provides for the controlled concentration and thickness of the doped TM region that is integrated into the bulk β-Ga₂O₃ substrate.

### CROSS-REFERENCE TO RELATED PATENT APPLICATIONS

This application claims the benefit of priority of U.S. Provisional Application No. 63/482,422 titled “DIFFUSED β-Ga₂O₃ PHOTOCONDUCTIVE DEVICES,” filed Jan. 31, 2023. The entirety of each application referenced in this paragraph is incorporated herein by reference.

### FEDERALLY SPONSORED RESEARCH OR DEVELOPMENT

This invention was made with Government support under Contract No. DE-AC52-07NA27344 awarded by the United States Department of Energy. The Government has certain rights in the invention.

### BACKGROUND

### Field

The present disclosure relates generally to optical devices comprising photoconductive β-Ga₂O₃ or alloys thereof such as photoconductive semiconductor switches (PCSS) and optically addressable light valves (OALVs).

### Description of the Related Art

Photoconductive semiconductor switches (PCSS) can be used to switch or modulate an electrical signal with an optical signal. The PCSS may comprise, for example, a photoconductive semiconductor with a pair of electrodes on opposite sides. One of the electrodes is a transparent or optically transmissive conductor to the wavelength of the modulating beam of light to permit optical access to the photoconductive semiconductor. A voltage may be applied between the pair of electrodes. The photoconductive semiconductor will have a different conductivity upon being illuminated with the modulated beam of light as compared to not being exposed to such light. The light may, for example, excite photocarriers that increase the conductivity of the photoconductive semiconductor. This change in conductivity with exposure to light thereby modulates the electrical signal that flows across the photoconductive semiconductor. Such a device may be employed as an optically controlled switch or modulator that switches on or off or modulates an electrical signal based on the modulation of the controlling beam of light incident thereon.

Optically addressable light valves (OALVs) are used to control the spatial shape and/or intensity distribution of laser beams. OALVs may comprise of a number of elements such as a photoconductor, a pair of transparent conductors (TCs), and liquid crystal. Two transparent conductors may be on opposite sides of the photoconductor and liquid crystal. The OALV may be operated by applying a voltage between the two transparent conductors and through the photoconductor and liquid crystal. The conductivity of the photoconductor is controlled with a control beam of light having a first wavelength, which generates charge carriers within the photoconductor material. This light may be spatially patterned, for example, by using a digital light projection system. At locations where the photoconductor becomes conductive, the voltage dropped across the photoconductor decreases and correspondingly increases across the liquid crystal. This increase in voltage across the liquid crystal actuates the liquid crystal at those locations. At the same time, an input beam of light from a laser or other light source that is to be spatially modulated or shaped is incident on the OALV. In the locations where the liquid crystal has changed state due to the increased voltage, the liquid crystal acts to change the polarization of the input beam. The input beam from the laser or light source then passes through a polarizer, allowing only light with the correct polarization to pass through. Depending on the design, the light from the control beam may cause the liquid crystal state to be such that the light passes or is blocked. OALVs can thus be used to control the intensity across the input light beam and therefore potentially alter the spatial shape and/or intensity distribution of the input beam in real time.

### SUMMARY

The present disclosure relates generally to designs for optical switches and optically addressable light valves. For example, various devices, systems and methods described herein include an optical switch or an optically addressable light valve comprising a high optical damage threshold ultra-wide band gap (UWBG) material such as Ga₂O₃, which has significantly higher laser induced damage thresholds than other designs. Use of such ultra-wide band gap semiconductors may enable higher intensity lasers.

In particular, various devices, systems and methods described herein employ β-Ga₂O₃ or alloys thereof as the photoconductive semiconductor. The β-Ga₂O₃ is doped with a transition metal (TM) such as copper to provide defect states (e.g., deep level traps) within the ultra wide band gap of the β-Ga₂O₃. In various designs, these defect states can provide conducting photocarriers when the transition metal doped semiconductor is illuminated with light of a sufficient energy to excite carriers from these defect states into, for example, the conduction band, thereby increasing the conductivity of the β-Ga₂O₃ layer.

More particularly, various implementations described herein include a photoconducting β-Ga₂O₃ layer having a transition metal (TM) doped region formed by diffusion of TM into a Ga₂O₃ substrate. The diffusion of the TM into the β-Ga₂O₃ substrate provides for the controlled concentration and thickness of the doped TM region that is integrated into the bulk β-Ga₂O₃ substrate. In various designs, the β-Ga₂O₃ is also doped with an n-type dopant to provide for n-doped β-Ga₂O₃. The n-type doping adds electrons to the material than can be trapped in the deep levels. The trapped electrons are then optically excited back into the conduction band to conduct. These structures can be superior to designs where the full wafer/chip thickness is doped with a transition metal because the photoresponsivity and capacitance can be tuned for desired, e.g., reduced, improved or optimal, device performance. The design may also potentially eliminate the need for costly crystal growth (e.g., bulk or epitaxial growth) equipment by creating the thin doped portion of the β-Ga₂O₃ by diffusion, although such a device could also be created using epitaxial growth. In various cases, the laser damage threshold of such device structures can be higher than a photoconductive β-Ga₂O₃ layer heterogeneously bonded to another substrate or optic (e.g., fused silica or BK7). Such diffused β-Ga₂O₃ photoconductor layers can be used to create photoconductive semiconductor switches (PCSS) and optically addressable light valves (OALV). Alloys of β-Ga₂O₃ may also be employed.

In various implementations, for example, a photoconductive semiconductor device comprises a first conductor, a layer of β-Ga₂O₃ or an alloy thereof, and a second conductor, wherein the second conductor is on an opposite side of the layer of β-Ga₂O₃ or alloy thereof than the first conductor. The layer of β-Ga₂O₃ or alloy thereof may include a region doped with transition metal. The transition metal doped region (a) has a thickness of no more than 100 micrometers, (b) has a gradient in concentration of the transition metal that decreases from an edge of the layer of β-Ga₂O₃ or alloy thereof, or (c) both. Additionally, at least one of the first and second conductors comprises an optically transmissive conductor layer.

Also disclosed herein is a photoconductive semiconductor device comprising a first conductor, a layer of β-Ga₂O₃ or an alloy thereof, and a second conductor, wherein the first conductor is on an opposite side of the layer of β-Ga₂O₃ or alloy thereof as the first conductor. The layer of β-Ga₂O₃ or alloy thereof includes a doped region with a transition metal diffused therein, and at least one of the first and second conductor layers is optically transmissive conductor layer.

Additionally, described herein is a method of forming a photoconductive semiconductor device. The method comprises providing a substrate of β-Ga₂O₃ or alloy thereof, diffusing a transition metal into the β-Ga₂O₃ or alloy substrate, providing a first conductor on one side of said β-Ga₂O₃ or alloy substrate (the first conductor being optically transmissive), and providing a second conductor layer on an opposite side of the β-Ga₂O₃ or alloy substrate as the first conductor layer.

As discussed above, alloys of β-Ga₂O₃ may also be employed. Such alloys may include, for example, alloys with aluminum (Al) or indium (In) such as for example, AlₓGa_{y}O₃ (Aluminum Gallium Oxide) or GaₓIn_{y}O₃ (Gallium Indium Oxide).

A wide range of other devices and methods are also described herein.

### BRIEF DESCRIPTION OF THE DRAWINGS

The drawings described herein are for illustrative purposes only of selected embodiments and not all possible implementations, and are not intended to limit the scope of the present disclosure.

Corresponding reference numerals indicate corresponding parts throughout the several views of the drawings.

FIG. 1 is a schematic cross-sectional view of a photoconductive semiconductor switch (PCSS) comprising a β-Ga₂O₃ semiconductor photoconductor having a transparent conductor and a metal contact on opposite sides. The β-Ga₂O₃ semiconductor photoconductor includes a diffused photoconductive region formed by diffusing transition metal into a β-Ga₂O₃ substrate.

FIGS. 2A and 2B are schematic cross-sectional views illustrating a method of diffusing transition metal into a Ga₂O₃ substrate. FIG. 2A is schematic cross-sectional view of a Ga₂O₃ substrate having a layer of transition metal such as copper (Cu) formed thereon. FIG. 2B is schematic cross-sectional view of the Ga₂O₃ substrate having the transition metal (e.g., Cu) diffused therein, for example, by heating the Ga₂O₃ substrate shown in FIG. 2A having the layer of transition metal formed thereon.

FIG. 3 is a schematic perspective view of an example of an optically addressable light valve (OALV).

FIG. 4 is a schematic cross-sectional view of an OALV including a β-Ga₂O₃ semiconductor photoconductor comprising a diffused photoconductive region formed by diffusing transition metal into a β-Ga₂O₃ substrate. The semiconductor photoconductor also has a transparent conductive region formed therein that provides a conductor for making electrical connection that is transparent or optically transmissive, for example, to the wavelength of light to be received by the optical device.

### DETAILED DESCRIPTION

As discussed above, β-Ga₂O₃ is an ultra-wide bandgap semiconductor that possesses outstanding physical properties for power electronics and optoelectronics. For example, β-Ga₂O₃ has a bandgap of about 4.8 eV and a high dielectric breakdown strength. These properties make β-Ga₂O₃ desirable as a photoconductive material for both photoconductive semiconductor switches (PCSS) and optically addressable light valves (OALV) if the material can be appropriately doped with both donors for producing n-type material as well as transition metals that form deep level states in the bandgap for providing useful photoconductivity responsiveness to, e.g., visible light or UV light. The n-type dopants supply electrons to the β-Ga₂O₃ to be optically excited. These electrons will exist in the conduction band and the material will be conductive. Transition metals can be added to provide trap states mid gap that the electrons fall into, namely, electrons will fall from the conduction band to the trap states. If trap states are filled, the electrons in the traps can be optically excited back to the conduction band so that these carriers are mobile providing for conduction or increased conduction. Thus, when the light is off, the electrons are re-trapped and the material is less conductive and if the number of trap states exceeds the number of n-type dopants, no longer conductive. Generally, examples of n-type dopants include silicon (Si), germanium (Ge), and tin (Sn).

N-type doping can enable creation of free electrons in β-Ga₂O₃ and can be reliably controlled in both bulk and epitaxial material. To tailor the photoconducting properties of β-Ga₂O₃, dopants are incorporated into the crystal lattice as referenced above. These dopants can include a range of transition metal dopants that can be introduced to create defect energy levels at desired locations within the bandgap. While a desired TM could be included in bulk crystals during the growth of the crystalline structure, this approach may incur substantial commercial development costs to both optimize growth conditions to incorporate the new dopant and to dedicate growth equipment for each particular dopant. Furthermore, different applications may involve different thicknesses of the TM-doped region. For some applications, to achieve desired small thickness, a TM-doped wafer itself needs to be thinned to the desired photoconductor thickness. These thin layers, however, can become extremely fragile and increasingly difficult to process. Bonding a thinned wafer to other another material is also likely to suffer from laser damage at the bond interface when used in high power optoelectronics.

Accordingly, although TM-doped layers could be grown by epitaxy to realize various device designs described herein such as for PCSS and an OALV devices, development costs to develop the growth conditions for each dopant may be high. Moreover, growing layers tens of microns thick can be challenging, expensive, and potentially impractical.

Accordingly, as described herein prototypical photoconductive β-Ga₂O₃ devices can be formed through diffusion of TM's into commercially available β-Ga₂O₃ material. Using diffusion of TM into the β-Ga₂O₃, the thickness of the TM doped β-Ga₂O₃ photoconductive layer can be tailored without the need to grow TM doped epitaxial layers or thin down doped bulk wafers. The equipment for creating the devices and photoconductive layers described herein may also be significantly cheaper and less complex than crystal growth equipment.

Two example device types that employ such TM diffused β-Ga₂O₃ photoconductive layers, a PCSS and an OALV, are described below. Diffused β-Ga₂O₃ PCSS's and OALV's can be advantageous over similar SiC and Diamond devices because dopants may not be as easily diffused into these later materials. Therefore, thin SiC and Diamond devices may need to be created from thinning doped bulk wafers and/or growing thick epitaxial layers. Discussions herein relating to β-Ga₂O₃ are to be understood to apply to and include alloys of β-Ga₂O₃. Such alloys may include, for example, alloys with aluminum (Al) or indium (In). Aluminum can be added to increase the bandgap. Indium can be used to decrease the bandgap. Accordingly, the alloy may comprise, for example, AlₓGa_{y}O₃ (Aluminum Gallium Oxide) or GaₓIn_{y}O₃ (Gallium Indium Oxide). Likewise, alloys in the aluminum gallium indium oxide material systems could be used. Other alloys may also be employed.

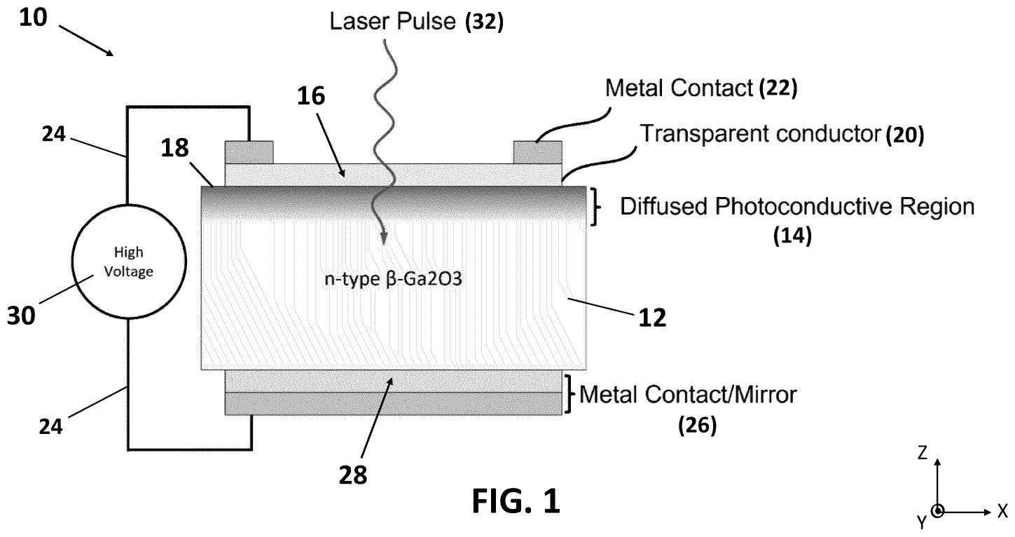

FIG. 1 depicts an example photoconductive semiconductor device 10, and in particular, a photoconductive semiconductor switch (PCSS), comprising a diffused β-Ga₂O₃ photoconductor layer 12. In this example, the diffused β-Ga₂O₃ photoconductor layer 12 comprises n-type β-Ga₂O₃ containing n-type dopant to produce n-type semiconductor material from the β-Ga₂O₃. In various implementations, the n-type dopant may be introduced as the β-Ga₂O₃ crystal is grown or formed expitaxially. Silicon, Germanium, Tin, Hafnium, Zirconium, Tantalum. Silicon, Germanium and Sn may, for example, be used for n-type doping.

In the example shown, however, the β-Ga₂O₃ photoconductor layer 12 has a region 14 that includes transition metals diffused therein. These transition metals diffused into the β-Ga₂O₃ photoconductor layer 12 may have the effect of introducing defect states within the wide band gap of the β-Ga₂O₃ semiconductor material causing the semiconductor to be a photoconductor responsive to wavelengths having less energy than the band gap. For example, although the size of the bandgap of β-Ga₂O₃ may correspond to a deep ultraviolet wavelength, light having less energy or longer wavelengths, such as possibly UV, visible or infrared light, may be sufficient to energize photocarriers in the defect states produced by the diffusion of the TM into the β-Ga₂O₃ into the conduction band.

As illustrated, the TM doped region 14 of the β-Ga₂O₃ layer 12 is on one side 16 of the β-Ga₂O₃ layer. In particular, the TM doped region 14 of the β-Ga₂O₃ layer 12 is on an edge 18 or surface of the of the β-Ga₂O₃ layer 12. As discussed herein, the TM doped region 14 of the β-Ga₂O₃ layer 12 is formed by diffusing TM into the β-Ga₂O₃ layer. The result is a TM concentration that varies with longitudinal distance into the β-Ga₂O₃ layer (e.g., in the direction parallel to the z-axis of the xyz coordinate system in the lower right corner of FIG. 1). This distribution of TM and variation of TM concentration with longitudinal distance into the β-Ga₂O₃ layer 12 will be consistent with diffusion of TM therein and may fall-off exponentially as a Gaussian or complimentary error function. As illustrated, the TM doped region 14 of the β-Ga₂O₃ layer 12 comprises a region of the β-Ga₂O₃ layer 12. Similarly, the thickness (e.g., dimension in the longitudinal direction parallel to the z-axis orthogonal to the surface 18) of the TM doped region 14 is a fraction of the thickness of the β-Ga₂O₃ layer 12. This thickness may, for example be 500 micrometers or less, 400 micrometers or less, 300 micrometers or less, 200 micrometers or less, 100 micrometers or less, 80 micrometers or less, 70 micrometers or less, 60 micrometers or less, 50 micrometers or less, 40 micrometers or less, 30 micrometers or less, 20 micrometers or less, 15 micrometers or less, 10 micrometers or less, 5 micrometers or less, 3 micrometers or less or 1 micrometer or less or any range between any of these values. This thickness may also be, for example, 400 micrometers or more, 300 micrometers or more, 200 micrometers or more, 100 micrometers or more, 80 micrometers or more, 70 micrometers or more, 60 micrometers or more, 50 micrometers or more, 40 micrometers or more, 30 micrometers or more, 20 micrometers or more, 15 micrometers or more, 10 micrometers or more, 5 micrometers or more, 3 micrometers or more or 1 micrometer or more, 1 micrometer or more, or any range between any of these values. In some cases, the thickness of the TM doped region may correspond to the thickness of the region where the trap density exceeds the n-type donor density. At the location where the trap density no longer exceed the n-type donor density, the TM doped region becomes conductive even without light. That is, not all of the electrons are trapped and are thus free to conduct. In some cases, the thickness of the TM doped region is determined based on the lower detection limit of a concentration profiling technique used to measure the concentrations such as secondary ion mass spectrometry (SIMS). The lower bound for measuring the concentration may be different for different element/semiconductor systems, but may be generally around 1×10¹⁶ cm⁻³. This thickness can be controlled by adjusting the process parameters used when diffusing the TM into the β-Ga₂O₃ layer 12. In various example designs, the TM may be copper (Cu), silver (Ag), or molybdenum (Mo), although other transition metals may be employed.

A first conductor 20 comprising a transparent or optically transmissive conductor 20 is on one side 16 of the β-Ga₂O₃ layer 12. In various implementations, this transparent or optically transmissive conductor 20 is optically transmissive to light having a wavelength that excites carriers from the defect states formed by diffusing TM into the β-Ga₂O₃ layer 12 such that these carriers transition into the conduction band causing the β-Ga₂O₃ layer, and more particularly, the diffused photoconductive region 14, to be more conducting. Similarly, in various implementations, this transparent or optically transmissive conductor 20 is optically transmissive to light used to control, e.g., switch or modulate, the device 10. In various implementations, the first conductor 20 is deposited or otherwise formed on the β-Ga₂O₃ layer 12 although in some implementations, an intervening layer may be disposed between the transparent or optically transmissive 20 and the β-Ga₂O₃ layer 12. As shown, in some designs, the first conductor 20 is deposited or otherwise formed on the TM doped region 14 of the β-Ga₂O₃ layer 12 although in some designs, an intervening layer may be disposed between the first conductor 20 and the β-Ga₂O₃ layer 12. In various designs, the transparent conductor 20 comprises a transparent conducting oxide (e.g., ITO, FTO, etc.), an epitaxially grown β-Ga₂O₃ n-type layer, a thin metallic layer, or any combination of these. As illustrated, an ohmic metal contact or other contact 22 is formed on the transparent conductor 20 to ease electrical interfacing with the switch 10. Electrical leads, lines and/or wiring 24 may be electrically connected to the contact 22, for example, as schematically shown in FIG. 1.

In the design depicted in FIG. 1, a second conductor 26 comprising a metal contact is positioned in contact with the n-type β-Ga₂O₃ layer 12 on the opposite side 28 of the β-Ga₂O₃ layer as the first conductor 20 comprising the transparent or optically transmissive conductor. In this design, this metal contact 26 forms an ohmic contact for electrically connecting electrical lines, leads, and/or wiring 24 to the other side 28 of the β-Ga₂O₃ layer 12. This metal contact comprise a stack of metal layers that additionally operate as an optical reflector or mirror. In this example device, the metal contact 26 comprises silver (Ag) or aluminum (Al) and gold (Au) although other materials and other combinations are possible. The metal contact/mirror 26 comprises a pair of discrete metal layers. Aluminum (Al) and silver (Ag) are good reflectors and may comprise one of the layers, e.g., the inner layer closer to the β-Ga₂O₃ layer 12. The metal contact can have a gold (Au) layer on the outside (farther from the β-Ga₂O₃ layer 12), for example, because gold (Au) does not oxidize and easily forms a good electrical connection. In some implementations, however, the metal contact/mirror 26 could instead be an optically transmissive electrical contact, for example, same as (or different from) the other optically transmissive or transparent conductor 20. In certain designs, for example, illumination could be provided from both sides of the device 10 at once.

As discussed above, the first and second conductors 20, 26 can be electrically connected via electrical leads, lines, or wires to circuitry 30. In the example shown in FIG. 1, the circuitry 30 comprises a voltage source. When a voltage, for example, from the circuitry 30 is applied across the device 10, e.g., across the first and second conductors 20, 26 and thus across the transition metal doped region 14 of the β-Ga₂O₃ layer 12 therebetween, the device 10 can be switched on and off by modulating the conductivity of the diffused photoconductive region 14 using an external light beam 32. For example, when the conductivity is low, the switch is off and little or no current flows. When the conductivity is high, the switch is on. The conductivity could be controlled arbitrarily in between as well. Such a device can effectively transforms an optical signal in to an electrical signal out, in may in some respects therefore be considered an amplifier. The light 32 may be provided by a light source such as a pulsed laser or possibly other types of sources. Depending on the application and/or configuration, the light may be CW or pulsed.

As shown, the light 32 is incident on the device from the side 16 of the β-Ga₂O₃ layer 12 where the transparent or optically transmissive conductor 20 is located as opposed from the opposite side 28. Likewise in various such implementations, the transparent or optically transmissive conductor 20 comprises materially optically transmissive to the light 32 directed onto the device 10 use to modulate the device and the electrical signal from the circuitry 30.

In the example shown in FIG. 1, the TM doped region 14 is on the same side 16 of the β-Ga₂O₃ layer 12 in which the modulating light 32 is incident and thus also on the same side as the transparent or optically transmissive conductor 20. In an alternate design, the TM doped region 14 on the opposite side 28 of the of the β-Ga₂O₃ layer 12 as the transparent or optically transmissive conductor 20 and the side 16 on which the modulating light 32 is incident. Likewise, the TM doped region 14 can be on the same side as the second conductor 26, which in this example, is not transparent or optically transmissive 20 and comprises a mirror. Other variations are possible.

As discussed above, the TM dopant is diffused into the β-Ga₂O₃ layer 12 thereby forming the TM doped region 14. Employing diffusion to dope the β-Ga₂O₃ layer 12 with TM provides control over the thickness of the TM doped region 14. Consequently, a TM doped region 14 that is thin may be created. One possible significant advantage of using a thin TM doped region 14 is that less light may be needed to switch the device 10 on and off creating a more efficient design. Such a device 10 having a thin TM doped region 14 may also have a higher photo-responsivity, which is the amount of current generated per watt of optical power incident on the device, typically in units of (A/W)/(kV/cm), which is normalized for the electrical field.

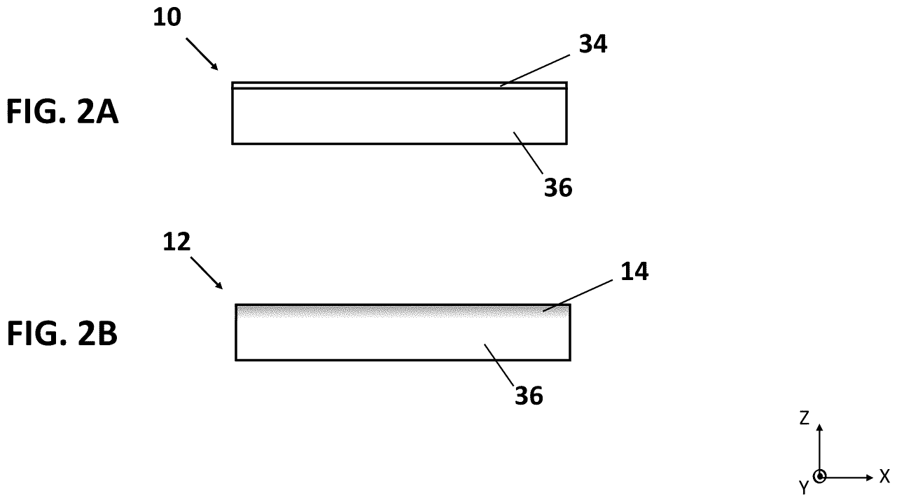

FIGS. 2A and 2B schematically illustrate a process for diffusing TM dopant into the β-Ga₂O₃ layer 12 thereby forming the TM doped region 14. As illustrated in FIG. 2A, a layer of TM 34 is formed on a β-Ga₂O₃ substrate 36. The β-Ga₂O₃ substrate 36 may comprise, for example, expitaxially grown β-Ga₂O₃ doped with an n-type dopant. The β-Ga₂O₃ substrate 36 may comprise a β-Ga₂O₃ crystalline die that may or may not be diced from a β-Ga₂O₃ crystalline wafer into the desired shape. The transition metal may be deposited on a surface of the β-Ga₂O₃ substrate 36 for example, using sputtering or evaporation or other deposition method. For example, a TM target may be sputtered to provide TM that is accumulated or deposited on the surface of the β-Ga₂O₃ substrate 36. Similarly, TM may be evaporated to provide TM vapor causing TM to be accumulated or deposited on the surface of the β-Ga₂O₃ substrate 36. Other methods may be used to deposit TM on the surface of the β-Ga₂O₃ substrate 36.

FIG. 2B schematically illustrates the β-Ga₂O₃ substrate 36 having the TM formed thereon being heated such that TM from the layer of TM 34 on the surface of the β-Ga₂O₃ substrate diffuses into the β-Ga₂O₃ substrate to form the diffused TM region 14 of the β-Ga₂O₃ layer 12. As illustrated, the TM concentration varies with longitudinal distance into the β-Ga₂O₃ layer 12 (e.g., direction parallel to the z-axis of the xyz coordinate system in the lower right corner of FIG. 1 and/or normal to the surface of the substrate 36). This distribution of TM and variation of TM concentration with longitudinal distance into the β-Ga₂O₃ layer 12 will be consistent with diffusion of TM therein and may fall-off exponentially as a Gaussian or complementary error function. The TM can be diffused to the desired depth and concentration by controlling the diffusion ambient (e.g., the gas or atmosphere present around workpiece or sample), temperature, and time or duration of heating. Other methods of diffusing the TM into the β-Ga₂O₃ substrate 36 may be employed and likewise other configurations for fabricating the β-Ga₂O₃ layer 12 having the diffuse region 14 therein may be used. For example, diffusing from a vapor source (e.g., of the TM or transition metal oxide) may be employed.

The β-Ga₂O₃ substrate 36 having the diffused TM region 14 produced by such a process may be employed in optical devices 10 such as a PCSS as described above. Similarly, a β-Ga₂O₃ substrate 36 having the diffused TM region 14 produced by such a process as described above may be included in an optically addressable light valve.

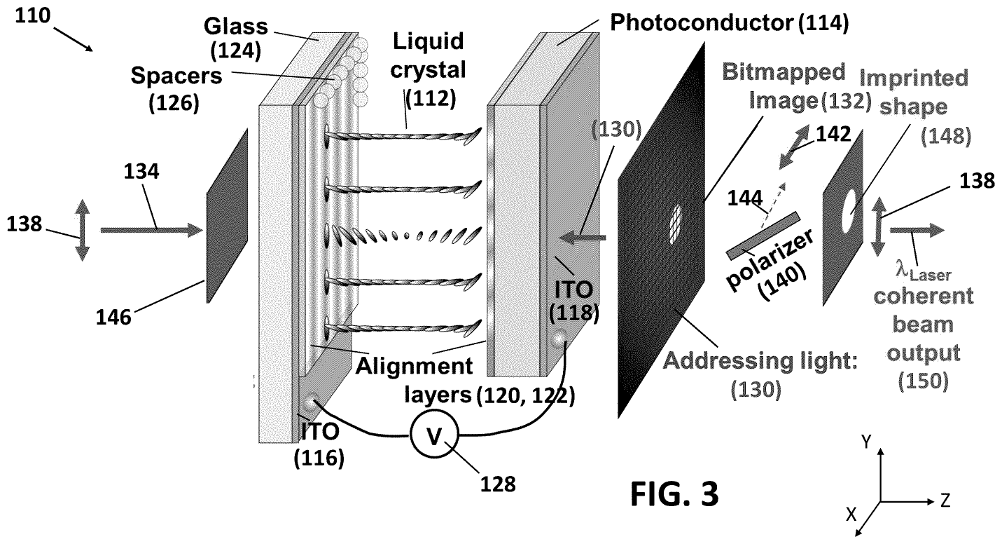

An optically addressable light valve (OALV) 110 such as shown in FIG. 3 may comprise a layer of liquid crystal 112 and a photoconductor 114 disposed between first and second transparent conductors (TCs) 116, 118. The photoconductor 114 may comprise β-Ga₂O₃ semiconductor having a TM doped region 14 formed by diffusing TM into a β-Ga₂O₃ substrate 36 such as by employing a process discussed above in connection with FIGS. 2A-2B. The first and second transparent conductors (TCs) 116, 118 may comprise indium tin oxide (ITO) in some designs. The OALV 110 may further comprise first and second alignment layers 120, 122 for aligning liquid crystal molecules adjacent thereto. A substrate 124, such as a glass substrate may provide support for the liquid crystal 112 and/or the device 110. Spacers 126 may be disposed between the substrate 124 and the photoconductor 114, and in the configuration shown in FIG. 3, between the alignment layers 120, 122 to provide a space for the liquid crystal layer 112. Electronic circuitry 128 such as a voltage source may be electrically connected to the first and second transparent conductors 116, 118 to apply a voltage therebetween. Such a voltage is thereby applied across the layer of liquid crystal 112 and the photoconductor layer 114.

As discussed above, the photoconductor 114 comprises β-Ga₂O₃, which is an ultra-wide band gap (UWBG) semiconductor. Accordingly, β-Ga₂O₃ can have superior laser induced damage threshold (LIDT) compared to various other OALV materials. Consequently, higher peak and average power lasers and laser beams may be employed in the OALVs 110 comprising such UWBG semiconductors.

The OALV system 110 may further comprise a projector (not shown) configured to provide a control beam 130 comprising addressing light that is directed to and incident on the β-Ga₂O₃ photoconductor layer 114. As illustrated, the control beam 130 may be incident on the photoconductor 114 from the opposite side as the liquid crystal layer 112 such that the control beam does not need to be transmitted through the liquid crystal layer to reach the photoconductor.

In various implementations, the control beam 130 has an intensity that is spatially modulated to provide for a patterned intensity. The projector may comprise, for example, a light source to produce the control beam 130 and a spatial light modulator to modulate the intensity of the control beam at different locations across the control beam. Accordingly, the control beam 130 may have a cross-section (e.g., parallel to the x-y plane of the xyz axis depicted in FIG. 3) that corresponds to a controlled intensity pattern or image 132. The variations in intensity at different locations across the cross-section of the control beam 130 (e.g., parallel to the xy plane in FIG. 1) will produce variations in the conduction of the photoconductor 114 at different locations on the photoconductor where the light from the control beam is incident on the photoconductor. For example, in various implementations, the control beam 130 may have a wavelength sufficiently short and the light therefore sufficiently energetic, to excite photocarriers in the β-Ga₂O₃ semiconductor photoconductor 114. Variation in the intensity of the control beam 130, for example, across a cross-section of the control beam orthogonal to its length, will produced a similar spatial variation in density of photocarriers in the photoconductor 114 that are generated by the control beam.

As discussed above, at locations on the photoconductor 114 where the photoconductor becomes more conductive and less resistive as a result of generation of photocarriers by the control beam 130, the voltage drop across the photoconductor decreases. The portion of the voltage applied across the layer of liquid crystal 112 by the voltage source 128 correspondingly increases with decrease in voltage across the photoconductor 114. This increase in voltage across the liquid crystal layer 112 actuates the liquid crystal, changing the state of the liquid crystal molecules at the locations of increased voltage. In various implementations, at the locations where the liquid crystal 112 has increased voltage, the liquid crystal may not act to change the polarization of light incident thereon whereas where the liquid crystal has a reduced voltage thereacross, the liquid crystal may act to change the polarization of the light incident thereon. For example, in some implementations, where there is little voltage across the liquid crystal (where the photoconductor is unilluminated and resistive), the liquid crystal rotates the polarization of the input beam. When the voltage is dropped across the liquid crystal (where the photoconductor is illuminated and conductive), then the input beam passes through without a polarization change. Although this describes a binary on and off operation, intermediate states are possible as well.

As discussed above, an input beam 134 of light to be acted on by the OALV may be directed onto the OALV 110 and the liquid crystal layer 112. This input beam 134 may originate from laser or light source (not shown in FIG. 3). This input beam 134 may, in some implementations, have a particular polarization state 138, such as a vertically linearly polarized state as shown in FIG. 3. This polarization state 138 may be changed by the liquid crystal layer 112 when the input light beam 134 passes through the liquid crystal layer that has been selectively activated by the change in voltage drop across the liquid crystal layer. As mentioned above, this spatial modulation in voltage drop across the liquid crystal layer 112 results when photocarriers are generated by exposing the β-Ga₂O₃ photoconductor 114 to the control beam 130 having a spatially modulated intensity across its cross-section. The liquid crystal layer 112 may rotate or otherwise alter the polarization 138 of portions of the input beam 30 that pass through regions of the liquid crystal layer that have been activated. The amount of polarization rotation may be determined by the amount of voltage increase across the liquid crystal layer 130 at that location, which may be determined by the amount of photocarriers generated in the β-Ga₂O₃ photoconductor 114, which may vary depending on the intensity of the control beam 130 at that location along the cross-section of the control beam orthogonal to its length.

In various implementations, the OALV 110 may include a polarizer 140 that receives the input beam 134 after being transmitted through the liquid crystal layer 112. This polarizer 140, may comprise, for example, a linear polarizer in some designs. The polarizer 140 in FIG. 3 comprises a polarization beamsplitter. This polarization beamsplitter may, for example, reflect light of one polarization state such as one linear polarization state (e.g., horizontal polarization) 142 and transmit light of another polarization state such as another linear polarization state (e.g., vertical polarization) corresponding to the polarization 138 of the input beam 134. The reflected light is shown in FIG. 3 as a beam 144 reflected from the polarization beamsplitter 140 and directed elsewhere. Other configurations are possible. For example, the polarization beamsplitter may reflect light 144 of the original polarization 138 of the input beam 134 and transmit light of the other polarization state 142 such that the more the liquid crystal layer 112 changes the polarization of the input beam 134, the more light is transmitted through the polarizer 140. Still other configurations are possible.

The selective spatial modulation of the liquid crystal layer 112 by the spatially modulated control beam 130 can therefore selectively spatially modulate the input beam 134. Accordingly, the intensity of the input beam 134 across a cross-section thereof orthogonal to its length (e.g., parallel to the xy plane in FIG. 3) may be altered from a first spatial intensity distribution 146 to a second spatial intensity distribution 148. This second spatial intensity distribution 148 may be therefore patterned as desired by the OALV 110. The OALV 110 thus has an output beam 150 with a spatial intensity distribution across the cross-section of the output beam orthogonal to its length (e.g., parallel to the xy plane in FIG. 3) that can be controlled by the intensity distribution of the control beam 130 across the cross-section of the control beam orthogonal to its length.

As discussed above, in various implementations described herein, impurity doping such as with TM dopants may be employed to create deep levels or color centers in order to enable below band gap photogeneration with, e.g., visible light or UV light, for example, with a wavelength of at least 350 nm or at least 365 nm. Examples of possible dopants in β-Ga₂O₃ may include copper, silver or molybdenum, but the dopants and semiconductor materials need not be limited to these.

Accordingly, the OALV 110 may comprise a semiconductor photoconductor 114, for example, that includes deep level color centers or dopants such that the semiconductor photoconductor generates photocarriers in response to receiving visible or UV light (e.g., longer wavelengths than 350 nm or 365 nm) light. Accordingly, such deep level color centers or dopants may have energy states deep within the band gap such that visible light or UV light such as long wavelength UV light can excite electrons from those deep level states nearer the conduction band than the valence band into the conduction band or holes from deep level hole states nearer the valence band than the conduction band into the valence band. This approach may advantageously reduce damage to the liquid crystal layer 112. Higher energy light such as deep UV light used in exciting an electron from the valence band to the conduction band of an ultra-high band gap semiconductor (or causing a hole to transition from the conduction band to the valence band) may be more likely to damage the liquid crystal than lower energy light such as visible light or possibly UV light (e.g., with a wavelength of at least 350 nm or 365 nm) that can be used to cause transitions from deep level states in the band gap into the conduction band or valence band. Accordingly, in various implementations, the semiconductor photoconductor 114 includes deep level color centers or dopants that allow the control beam 130 to have a wavelength in the UV (e.g., with of wavelength of 350 nm or longer) or visible range.

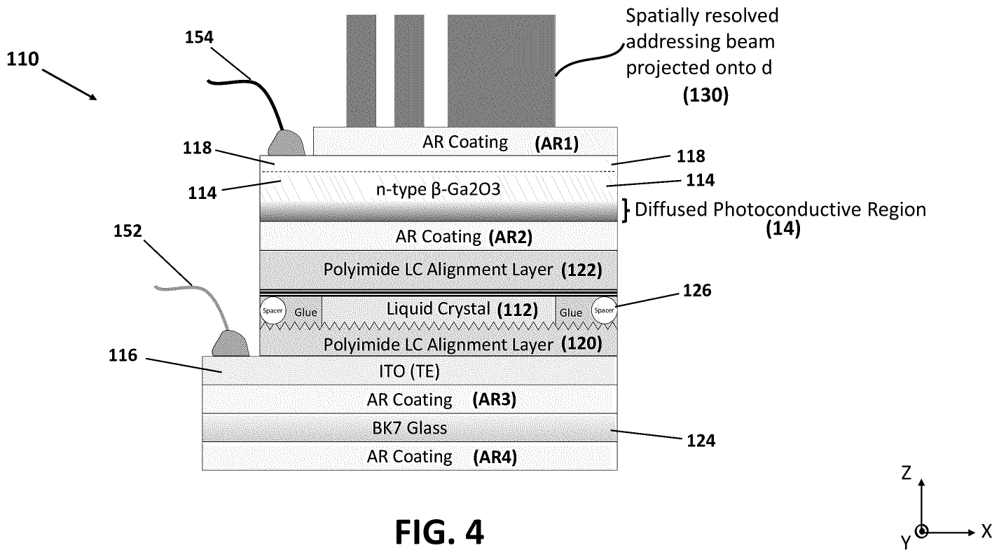

FIG. 4 depicts a schematic of another OALV 110 fabricated from a diffused β-Ga₂O₃ photoconductor 114. As discussed above, these devices 110 can be used to spatially shape lasers beams. The device 110 shown includes wafers/optics that are bonded (e.g., with glue or adhesive, etc.) together to form a liquid crystal (LC) cell encapsulating liquid crystal 112. As shown, the wafers/optics include alignment layers 120, 122 are on opposite sides of the liquid crystal layer 112. Spacers 126 separate the alignment layers and provide space for the region comprising the liquid crystal 112. Additionally, a substrate 124 (e.g., comprising glass such as BK7 glass) is on one side of the liquid crystal region 112 and, in the example shown, a β-Ga₂O₃ layer 114 on an opposite side of the liquid crystal. The device 110 shown in FIG. 4 includes an optically transmissive or transparent electrode 116 (e.g., indium tin oxide, ITO) electrically connected to a lead 152. Another lead 154 is electrically connected to the β-Ga₂O₃ layer 114 on a side of the β-Ga₂O₃ layer opposite the other electrode 116. In the design shown, the diffused photoconductive region 14 of the β-Ga₂O₃ layer 114 is on a side of the β-Ga₂O₃ layer 114 closer to the liquid crystal and the transparent or optically transmissive electrode and opposite the side of the β-Ga₂O₃ layer 114 where the addressing beam 130 is incident, however, other alternative configurations are possible.

Anti-reflective coatings AR1, AR2, AR3, AR4 are shown on various surfaces or interfaces to reduce reflection. For example, a first anti-reflective coating (AR1) is shown on the β-Ga₂O₃ layer 114, for example, on the side oppose the diffused TM region 14. A second anti-reflective (AR2) coating is between the photoconductor 114 (e.g., the diffused TM region 14) and the alignment layer 122. A third and fourth anti-reflective coatings (AR3, AR4) are on opposite sides of the optical flat 124, for example, on an exposed surface thereof.

In the example shown, a spatially resolved addressing beam (image) 130, is projected onto the top surface of the device 110 and onto the β-Ga₂O₃ layer 114, including the diffused TM region 14, which is photoconductive and responsive to the wavelength of the incident control beam. In the areas where the light 130 is incident to the photoconductor 114, 14, the photoconductor becomes conductive and locally transfers voltage to the liquid crystal 112. By controlling voltage to the liquid crystal 112, the main laser beam that is to be shaped (not shown) can be allowed to pass through or blocked by one or more external polarizers (not shown) depending on whether the liquid crystal is set to rotate that portion of the beam.

As in the example shown in FIG. 4, in some designs, the transparent or optically transmissive conductor 118 can be integrated with the β-Ga₂O₃ material of the β-Ga₂O₃ layer 114. A transparent or optically transmissive conductive region 118 may be formed in the semiconductor surface, for example, on a side opposite the liquid crystal layer 112. This transparent or optically transmissive conductor layer 118 may be formed in the β-Ga₂O₃ layer 114 on one side (e.g., the side opposite the liquid crystal 112) such that this transparent or optically transmissive conductor layer and the semiconductor photoconductor comprise a single monolithic structure as illustrated in FIG. 4. The conductive region 118 can be formed in the β-Ga₂O₃ layer 114 via impurity doping. Impurities in the semiconductor, for example, close to the surface of the β-Ga₂O₃ layer 114 (on the side of the β-Ga₂O₃ layer opposite the liquid crystal layer 112) may create a conductive region in the β-Ga₂O₃ layer. However, if the wafer before diffusion the TM is conductive, then an additional step to make the surface more conductively is likely not necessary since regions where the TM has not diffused should be conductive. The entire n-type region could effectively be the transparent conductor. The undiffused bulk part of the wafer would be n-type. However, the surface could be doped to be more conductive so that the voltage drop from the electrical contact 154 to the rest of the surface remains low. Accordingly, in various designs, β-Ga₂O₃ layer 114 includes a sufficiently high amount of impurity dopants on a side of said β-Ga₂O₃ layer opposite said liquid crystal 112 to form a conductive layer 118, this conductive layer being disposed in the β-Ga₂O₃ layer 114 (e.g., in, at or near the side of the β-Ga₂O₃ layer opposite the liquid crystal layer). In various implementations, these dopants comprise shallow donor dopants to provide room temperature conductivity. These shallow level dopants in the β-Ga₂O₃ layer 114 are sufficiently close in energy to the conduction band to provide significant room temperature conductivity and not need to be photo-excited to the conduction band to make the material conductive. Examples of such dopants can include, Si, Sn, Ge, e.g., for Ga₂O₃, although the dopants should not be limited to these.

As discussed above, a voltage source 128 may be electrically connected to this conductive region 118 of the β-Ga₂O₃ layer 114 and to the other transparent or optically transmissive electrode 116 to apply a voltage across at least a portion of the β-Ga₂O₃ layer and the TM doped photoconductor region 14 as well as the liquid crystal layer 112.

As discussed above, the device 110 includes a β-Ga₂O₃ layer 114 comprising a region 14 having TM diffused therein to cause the β-Ga₂O₃ to be photoconductive when illuminated with light 130 of the appropriate wavelength (e.g., for wavelengths corresponding to energies larger than the transition from the defect states introduced by the transmission metal into the conduction band of the β-Ga₂O₃).

Also as discussed above, diffusing the TM into the β-Ga₂O₃ layer 114 allows for control over the concentration and thickness of the region 14 having the TM diffused therein. Controlling the thickness of this photoconductor region 14 can be useful to both the operation and fabrication of an OALV. For example, the TM doped photoconductor region thickness can affect the operating frequency of the liquid crystal 112 due to series capacitance of the TM doped photoconductive region 14. Therefore, control of the thickness can be used to control this capacitance. Since the β-Ga₂O₃ is serving as an optic in addition to being a photoconductor, the β-Ga₂O₃ layer 114 may be sufficiently thick to prevent flexing of the wafer, which can cause unwanted distortion in the main beam. However, thick layers 14 on the order of the wafer thickness (e.g., the thickness of the β-Ga₂O₃ layer 114) may also involve more intense addressing light 130 to activate the liquid crystal 112 as the photoconductor layer being exited would have larger thickness. An alternative design involving mounting a thin TM doped β-Ga₂O₃ photoconductive layer to a thick substrate may fail due to laser damage at the β-Ga₂O₃/substrate interface caused by the main beam to be shaped. Laser damage can be the limiting factor in the operation of current OALV's. Accordingly, by diffusing the TM dopant into a thick bulk β-Ga₂O₃ optic to forming a smaller TM doped photoconductor region of β-Ga₂O₃ within the thicker bulk β-Ga₂O₃ optic, such an interface between different materials that is more susceptible to laser damage is eliminated thereby increasing the laser damage threshold of the device 110.

A sample of β-Ga₂O₃ with diffused copper (Cu) has been fabricated. Copper was diffused into the β-Ga₂O₃ at 900° C. in air for 20 hours. The Cu diffusion caused the β-Ga₂O₃ to have a reddish-brown color whereas locations on the β-Ga₂O₃ where copper was not diffused are water clear in color. β-Ga₂O₃ having copper diffused therein exhibited an absorption peak around ˜460 nm after the diffusion for two different crystal orientations of β-Ga₂O₃. This absorption peak is located in a desired region of the spectrum suitable for photoconduction.

A wide variety of variations in the devices, e.g., PCSS and OALV devices, configurations, system design and/or methods of use are possible. For example, either one or both of the electrodes or conductors 16, 28 of the PCSS device 10 shown in FIG. 1 may be integrated with the β-Ga₂O₃ material of the β-Ga₂O₃ layer 12. For example, the ITO layer 16 and the metal layer 28 in the PCSS can be replaced with highly doped Ga₂O₃ region of the β-Ga₂O₃ layer 14. Such a configuration may be useful if both side illumination is used. As discussed in connection with the OALV 110 shown in FIG. 4, a transparent or optically transmissive conductive region 118 may be formed in the surface of the β-Ga₂O₃ layer 114. This conductor 118 may be formed in the β-Ga₂O₃ layer 114 such that this conductor and the β-Ga₂O₃ layer 114 comprise a single monolithic structure such as illustrated in FIG. 4. The conductive region 118 can be formed in the β-Ga₂O₃ layer 114 via impurity doping. Impurities in the semiconductor, for example, close to the surface of the β-Ga₂O₃ layer 114 may create a conductive region in the β-Ga₂O₃ layer. Accordingly, in various designs, β-Ga₂O₃ layer 114 includes a sufficiently high amount of impurity dopants on one or both sides of said β-Ga₂O₃ layer to form one or more conductors or conductive region. In various implementations, these dopants comprise shallow donor dopants to provide room temperature conductivity. These shallow level dopants in the β-Ga₂O₃ layer 114 are sufficiently close in energy to the conduction band to provide significant room temperature conductivity and not need to be photo-excited to the conduction band to make the material conductive. Example of such dopants can include, Si, Sn, Ge, e.g., for Ga₂O₃, although the dopants should not be limited to these.

Additionally, as stated above, the discussions herein relating to β-Ga₂O₃ are to be understood to apply to and include alloys of β-Ga₂O₃ as well. Such alloys may include, for example, alloys with aluminum (Al) or indium (In). Aluminum can be added to increase the bandgap. Indium can be used to decrease the bandgap. Accordingly, the alloy may comprise, for example, AlₓGa_{y}O₃ (Aluminum Gallium Oxide) or GaₓIn_{y}O₃ (Gallium Indium Oxide). Likewise, alloys in the aluminum gallium indium oxide material systems could be employed. Other alloys may also be employed.

A wide variety of variations, however, are possible. For example, any of the features described herein can be combined with any other features described herein. Features can be added, removed and/or re-arranged. Similarly, method steps can be added, removed, and/or re-ordered. Other variations are also possible.

### EXAMPLES

This disclosure provides various examples of devices, systems, and methods. Some such examples include but are not limited to the following examples.

### Examples—Part I

1. An optically addressable light valve configured to spatially modulate the intensity of an input beam of light, said optically addressable light valve comprising:
a layer of β-Ga₂O₃ or alloy thereof;
a first optically transmissive conductor; and
a layer of liquid crystal on the opposite side of said layer of β-Ga₂O₃ or alloy thereof as said first optically transmissive conductor,
wherein said layer of β-Ga₂O₃ or alloy thereof includes a region doped with transition metal, said region having (a) a thickness of no more than 100 micrometers, (b) a gradient in concentration of said transition metal that decreases from an edge of said layer of β-Ga₂O₃ or alloy thereof, or (c) both.

2. The optically addressable light valve of Example 1, wherein said transition metal doped region has a thickness of no more than 100 micrometers.

3. The optically addressable light valve of Example 2, wherein said transition metal doped region has a thickness of at least 50 micrometers.

4. The optically addressable light valve of Example 1, wherein said transition metal doped region has a thickness of no more than 50 micrometers.

5. The optically addressable light valve of Example 4, wherein said transition metal doped region has a thickness of at least 20 micrometers.

6. The optically addressable light valve of Example 1, wherein said transition metal doped region has a thickness of no more than 20 micrometers.

7. The optically addressable light valve of Example 6, wherein said transition metal doped region has a thickness of at least 10 micrometers.

8. The optically addressable light valve of Example 1, wherein said transition metal doped region has a thickness of no more than 10 micrometers.

9. The optically addressable light valve of Example 8, wherein said transition metal doped region has a thickness of at least 5 micrometers.

10. The optically addressable light valve of any of the examples above, wherein said transition metal doped region has a gradient in concentration of said transition metal that decreases from an edge of said layer of β-Ga₂O₃ or alloy thereof.

11. The optically addressable light valve of Example 10, wherein said gradient in concentration of said transition metal decreases in a manner consistent with diffusing said transition metal into said layer of β-Ga₂O₃ or alloy thereof.

12. The optically addressable light valve of Example 10 or 11, wherein said gradient in concentration of said transition metal follows a gaussian or complementary error function falloff.

13. The optically addressable light valve of any of the examples above, wherein said transition metal comprises copper.

14. The optically addressable light valve of any of the examples above, wherein said transition metal comprises silver or molybdenum.

15. The optically addressable light valve of any of the examples above, wherein said transition metal doped region further comprises an additional different dopant than said transition metal.

16. The optically addressable light valve of Example 15, wherein said additional different dopant comprises Si, Ge, or Sn.

17. The optically addressable light valve of any of the examples above, wherein said first optically transmissive conductor is formed in said layer of β-Ga₂O₃ or alloy thereof on one side such that said first optically transmissive conductor and said layer of β-Ga₂O₃ or alloy thereof comprise a single monolithic structure.

18. The optically addressable light valve of any of the examples above, further comprising a second optically transmissive conductor, said liquid crystal between said first and second optically transmissive conductors.

19. The optically addressable light valve of Example 1-9 and 13-18, wherein said layer of β-Ga₂O₃ is epitaxially grown with said transition metal in said doped region.

20. The optically addressable light valve of any of the examples above, wherein said optically addressable light valve is configured to apply a voltage across said liquid crystal and said layer of β-Ga₂O₃.

21. The optically addressable light valve of any of the examples above, wherein said transition metal dopants cause the transition metal doped region of said layer of β-Ga₂O₃ of alloy thereof to generate photocarriers in response to receiving visible light or ultraviolet light having a wavelength of at least 350 nm.

22. The optically addressable light valve of any of the examples above, wherein at least said first conductor is optically transmissive to a wavelength of visible light or ultraviolet light.

23. An optically addressable light valve configured to spatially modulate the intensity of an input beam of light, said optically addressable light valve comprising:
a layer of β-Ga₂O₃ or alloy thereof;
a first optically transmissive conductor; and
a layer of liquid crystal, said layer of liquid crystal on the opposite side of said layer of β-Ga₂O₃ or alloy thereof as said first optically transmissive conductor,
wherein said layer of β-Ga₂O₃ or alloy thereof includes a doped region with a transition metal diffused therein.

24. The optically addressable light valve of Example 23, wherein said transition metal doped region has a thickness of no more than 100 micrometers.

25. The optically addressable light valve of Example 24, wherein said transition metal doped region has a thickness of at least 50 micrometers.

26. The optically addressable light valve of Example 23, wherein said transition metal doped region has a thickness of no more than 50 micrometers.

27. The optically addressable light valve of Example 26, wherein said transition metal doped region has a thickness of at least 20 micrometers.

28. The optically addressable light valve of Example 23, wherein said transition metal doped region has a thickness of no more than 20 micrometers.

29. The optically addressable light valve of Example 28, wherein said transition metal doped region has a thickness of a least 10 micrometers.

30. The optically addressable light valve of Example 23, wherein said transition metal region has a thickness of no more than 10 micrometers.

31. The optically addressable light valve of Example 30, wherein said transition metal doped region has a thickness of a least 5 micrometers.

32. The optically addressable light valve of any of Examples 23-31, wherein said transition metal doped region has a gradient in concentration of said transition metal that decreases from an edge of said layer of β-Ga₂O₃ or alloy thereof.

33. The optically addressable light valve of Example 32, wherein said gradient in concentration of said transition metal decreases in a manner consistent with diffusing said transition metal into said layer of β-Ga₂O₃ or alloy thereof.

34. The optically addressable light valve of Example 32 or 33, wherein said gradient in concentration of said transition metal follows a gaussian or complementary error function falloff.

35. The optically addressable light valve of any of Examples 23-34, wherein said transition metal comprises copper.

36. The optically addressable light valve of any of Examples 23-34, wherein said transition metal comprises silver or molybdenum.

37. The optically addressable light valve of any of Examples 23-36, wherein said transition metal doped region further comprises an additional different dopant.

38. The optically addressable light valve of Example 37, wherein said additional different dopant comprises Si, Ge, or Sn.

39. The optically addressable light valve of any of Examples 23-38, wherein said first optically transmissive conductor is formed in said layer of β-Ga₂O₃ or alloy thereof on one side such that said first optically transmissive conductor and said layer of β-Ga₂O₃ or alloy thereof comprise a single monolithic structure.

40. The optically addressable light valve of any of Examples 23-39, further comprising a second optically transmissive conductor, said liquid crystal between said first and second optically transmissive conductors.

41. The optically addressable light valve of any of Examples 23-40, wherein said layer of β-Ga₂O₃ or alloy thereof includes a sufficiently high amount of impurity dopants on a side of said layer of β-Ga₂O₃ or alloy thereof opposite said first optically transmissive conductor to form a second conductor, said second conductor disposed in said layer of β-Ga₂O₃ or alloy thereof.

42. The optically addressable light valve of Example 23-31 and 35-41, wherein said layer of β-Ga₂O₃ or alloy thereof is epitaxially grown with said transition metal in said transition metal doped region.

43. The optically addressable light valve of any of Examples 23-42, wherein said optically addressable light valve is configured to apply a voltage across said liquid crystal and said region doped with transition metal in said layer of β-Ga₂O₃ or alloy thereof.

44. The optically addressable light valve of any of Examples 23-43, wherein said transition metal dopants cause the region doped with transition metal in said layer of β-Ga₂O₃ or alloy thereof to generate photocarriers in response to receiving visible light or ultraviolet light having a wavelength of at least 350 nm.

45. The optically addressable light valve of any of Examples 23-44, wherein at least said first conductor is optically transmissive to a wavelength of visible or ultraviolet light.

46. The optically addressable light valve of any of Examples 1-45, wherein said layer of β-Ga₂O₃ or alloy thereof comprises a layer of β-Ga₂O₃.

47. The optically addressable light valve of any of Examples 1-45, wherein said layer of β-Ga₂O₃ or alloy thereof comprises a layer of a β-Ga₂O₃ alloy.

48. The optically addressable light valve of Example 47, wherein said layer of β-Ga₂O₃ alloy comprises an alloy with aluminum or indium.

49. The optically addressable light valve of Example 48, wherein said layer of β-Ga₂O₃ alloy comprises GaₓIn_{y}O₃ (Gallium Indium Oxide).

50. The optically addressable light valve of Example 48, wherein said layer of β-Ga₂O₃ alloy comprises AlₓGa_{y}O₃ (Aluminum Gallium Oxide).

### Examples—Part II

1. A photoconductive semiconductor switch configured to optically modulate electricity, said photoconductive semiconductor switch comprising:
a first conductor;
a layer of β-Ga₂O₃ or alloy thereof, said layer of β-Ga₂O₃ or alloy thereof including a region doped with transition metal, said doped region (a) having a thickness of no more than 100 micrometers, (b) having a gradient in concentration of said transition metal that decreases from an edge of said layer of β-Ga₂O₃ or alloy thereof, or (c) both; and
a second conductor, said second conductor on an opposite side of said layer of β-Ga₂O₃ or alloy thereof than said first conductor,
wherein at least one of said first and second conductors comprises an optically transmissive conductor.

2. The photoconductive semiconductor switch of Example 1, wherein said transition metal doped region has a thickness of no more than 100 micrometers.

3. The photoconductive semiconductor switch of Example 2, wherein said transition metal doped region has a thickness of at least 50 micrometers.

4. The photoconductive semiconductor switch of Example 1, wherein said transition metal doped region has a thickness of no more than 50 micrometers.

5. The photoconductive semiconductor switch of Example 4, wherein said transition metal doped region has a thickness of at least 20 micrometers.

6. The photoconductive semiconductor switch of Example 1, wherein said transition metal doped region has a thickness of no more than 20 micrometers.

7. The photoconductive semiconductor switch of Example 6, wherein said transition metal doped region has a thickness of at least 10 micrometers.

8. The photoconductive semiconductor switch of Example 1, wherein said transition metal doped region has a thickness of no more than 10 micrometers.

9. The photoconductive semiconductor switch of Example 8, wherein said transition metal doped region has a thickness of at least 5 micrometers.

10. The photoconductive semiconductor switch of any of the examples above, wherein said transition metal doped region has a gradient in concentration of said transition metal that decreases from an edge of said layer of β-Ga₂O₃ or alloy thereof.

11. The photoconductive semiconductor switch of Example 10, wherein said gradient in concentration of said transition metal decreases in a manner consistent with diffusing said transition metal into said layer of β-Ga₂O₃ or alloy thereof.

12. The photoconductive semiconductor switch of Example 10 or 11, wherein said gradient in concentration of said transition metal follows a gaussian or complementary error function falloff.

13. The photoconductive semiconductor switch of any of the examples above, wherein said transition metal comprises copper.

14. The photoconductive semiconductor switch of any of the examples above, wherein said transition metal comprises silver or molybdenum.

15. The photoconductive semiconductor switch of any of the examples above, wherein said layer of β-Ga₂O₃ or alloy thereof further comprises an additional different dopant than said transition metal.

16. The photoconductive semiconductor switch of Example 15, wherein said additional different dopant is selected from Si, Ge, or Sn.

17. The photoconductive semiconductor switch of any of the examples above, wherein said first conductor is formed in said layer of β-Ga₂O₃ or alloy thereof on one side such that said first conductor and said layer of β-Ga₂O₃ or alloy thereof comprise a single monolithic structure.

18. The photoconductive semiconductor switch of any of the examples above, further comprising a second conductor, said first and second conductors on opposite sides of said layer of β-Ga₂O₃ or alloy thereof.

19. The photoconductive semiconductor switch of any of the examples above, wherein said layer of β-Ga₂O₃ or alloy thereof includes a sufficiently high amount of impurity dopants on a side of said layer of β-Ga₂O₃ or alloy thereof opposite said first conductor to form a second conductor, said second conductor disposed in said layer of β-Ga₂O₃ or alloy thereof.

20. The photoconductive semiconductor switch of Example 1-9 and 13-19, wherein said layer of β-Ga₂O₃ or alloy thereof is epitaxially grown with said transition metal in said doped region.

21. The photoconductive semiconductor switch of any of the examples above, wherein said photoconductive semiconductor switch is configured to apply a voltage across said region doped with transition metal in said layer of β-Ga₂O₃ or alloy thereof.

22. The photoconductive semiconductor switch of any of the examples above, wherein said transition metal dopants cause the region doped with transition metal in said layer of β-Ga₂O₃ to generate photocarriers in response to receiving visible light or ultraviolet light having a wavelength of at least 350 nm.

23. The photoconductive semiconductor switch of any of the examples above, wherein at least one of said first and second conductors is optically transmissive to a wavelength of visible or ultraviolet light.

24. A photoconductive semiconductor switch configured to optically modulate electricity, said photoconductive semiconductor switch comprising:
a first conductor;
a layer of β-Ga₂O₃ or alloy thereof; and
a second conductor, said second conductor on the opposite side of said layer of β-Ga₂O₃ or alloy thereof as said first conductor,
wherein said layer of β-Ga₂O₃ or alloy thereof includes a doped region with a transition metal diffused therein, and
wherein at least one of said first and second conductors comprises an optically transmissive conductor layer.

25. The photoconductive semiconductor switch of Example 24, wherein said transition metal doped region has a thickness of no more than 100 micrometers.

26. The photoconductive semiconductor switch of Example 25, wherein said transition metal doped region has a thickness of at least 50 micrometers.

27. The photoconductive semiconductor switch of Example 24, wherein said transition metal doped region has a thickness of no more than 50 micrometers.

28. The photoconductive semiconductor switch of Example 27, wherein said transition metal doped region has a thickness of at least 20 micrometers.

29. The photoconductive semiconductor switch of Example 24, wherein said transition metal doped region has a thickness of no more than 20 micrometers.

30. The photoconductive semiconductor switch of Example 29, wherein said transition metal doped region has a thickness of at least 10 micrometers.

31. The photoconductive semiconductor switch of Example 24, wherein said transition metal doped region has a thickness of no more than 10 micrometers.

32. The photoconductive semiconductor switch of Example 31, wherein said transition metal doped region has a thickness of at least 5 micrometers.

33. The photoconductive semiconductor switch of any of Examples 24-32, wherein said transition metal doped region has a gradient in concentration of said transition metal that decreases from an edge of said layer of β-Ga₂O₃ or alloy thereof.

34. The photoconductive semiconductor switch of Example 33, wherein said gradient in concentration of said transition metal decreases in a manner consistent with diffusing said transition metal into said layer of β-Ga₂O₃ or alloy thereof.

35. The photoconductive semiconductor switch of Example 33 or 34, wherein said gradient in concentration of said transition metal follows a gaussian or complementary error function falloff.

36. The photoconductive semiconductor switch of any of Examples 24-35, wherein said transition metal comprises copper.

37. The photoconductive semiconductor switch of any of Examples 24-35, wherein said transition metal comprises silver or molybdenum.

38. The photoconductive semiconductor switch of any of Examples 24-37, wherein said layer of β-Ga₂O₃ or alloy thereof further comprises an additional different dopant than said transition metal.

39. The photoconductive semiconductor switch of Example 38, wherein said additional different dopant comprises Si, Ge, or Sn.

40. The photoconductive semiconductor switch of any of Examples 24-39, wherein said first conductor is formed in said layer of β-Ga₂O₃ on one side such that said first conductor and said layer of β-Ga₂O₃ or alloy thereof comprise a single monolithic structure.

41. The photoconductive semiconductor switch of any of Examples 24-39, further comprising a second conductor, said first and second conductors on opposite sides of said layer of β-Ga₂O₃ or alloy thereof.

42. The photoconductive semiconductor switch of any of Examples 24-39, wherein said layer of β-Ga₂O₃ or alloy thereof includes a sufficiently high amount of impurity dopants on a side of said layer of β-Ga₂O₃ or alloy thereof opposite said first conductor to form a second conductor, said second conductor disposed in said layer of β-Ga₂O₃ or alloy thereof.

43. The photoconductive semiconductor switch of Example 24-32 and 36-42, wherein said layer of β-Ga₂O₃ or alloy thereof is epitaxially grown with said transition metal in said transition metal doped region.

44. The photoconductive semiconductor switch of any of the Examples 24-43, wherein said photoconductive semiconductor switch is configured to apply a voltage across said region doped with transition metal in said layer of β-Ga₂O₃ or alloy thereof.

45. The photoconductive semiconductor switch of any of the examples above, wherein said transition metal dopants cause the region doped with transition metal in said layer of β-Ga₂O₃ or alloy thereof to generate photocarriers in response to receiving visible light or ultraviolet light having a wavelength of at least 350 nm.

46. The photoconductive semiconductor switch of any of Examples 1-45, wherein said layer of β-Ga₂O₃ or alloy thereof comprises a layer of β-Ga₂O₃.

47. The photoconductive semiconductor switch of any of Examples 1-45, wherein said layer of β-Ga₂O₃ or alloy thereof comprises a layer of a β-Ga₂O₃ alloy.

48. The photoconductive semiconductor switch of Example 47, wherein said layer of β-Ga₂O₃ alloy comprises an alloy with aluminum or indium.

49. The photoconductive semiconductor switch of Example 48, wherein said layer of β-Ga₂O₃ alloy comprises GaₓIn_{y}O₃ (Gallium Indium Oxide).

50. The photoconductive semiconductor switch of Example 48, wherein said layer of β-Ga₂O₃ alloy comprises AlₓGa_{y}O₃ (Aluminum Gallium Oxide).

### Examples—Part III

1. A method of forming an optically addressable light valve configured to spatially modulate the intensity of an input beam of light, said method comprising:
providing a substrate of β-Ga₂O₃ or β-Ga₂O₃ alloy,
diffusing a transition metal into said β-Ga₂O₃ or β-Ga₂O₃ alloy substrate;
providing a first conductor on one side of said β-Ga₂O₃ or β-Ga₂O₃ alloy substrate, said first conductor layer being optically transmissive;
providing a layer of liquid crystal on another side of said β-Ga₂O₃ or β-Ga₂O₃ alloy substrate such that said β-Ga₂O₃ or β-Ga₂O₃ alloy substrate is between said first transparent conductor layer and said liquid crystal; and
providing a second conductor layer on a side of said liquid crystal opposite said first conductor layer.

2. The method of Example 1, wherein said transition metal is diffused into said β-Ga₂O₃ or β-Ga₂O₃ alloy substrate no more than 100 micrometers.

3. The method of Example 2, wherein said transition metal is diffused into said β-Ga₂O₃ or β-Ga₂O₃ alloy substrate at least 50 micrometers.

4. The method of Example 1, wherein said transition metal is diffused into said β-Ga₂O₃ or β-Ga₂O₃ alloy substrate no more than 50 micrometers.

5. The method of Example 4, wherein said transition metal is diffused into said β-Ga₂O₃ or β-Ga₂O₃ alloy substrate at least 30 micrometers.

6. The method of Example 1, wherein said transition metal is diffused into said β-Ga₂O₃ or β-Ga₂O₃ alloy substrate no more than 20 micrometers.

7. The method of Example 6, wherein said transition metal is diffused into said β-Ga₂O₃ or β-Ga₂O₃ alloy substrate at least 10 micrometers.

8. The method of Example 1, wherein said transition metal is diffused into said β-Ga₂O₃ or β-Ga₂O₃ alloy substrate no more than 10 micrometers.

9. The method of Example 8, wherein said transition metal is diffused into said β-Ga₂O₃ or β-Ga₂O₃ alloy substrate at least 5 micrometers.

10. The method of any of the examples above, wherein said transition metal is diffused into said β-Ga₂O₃ or β-Ga₂O₃ alloy substrate by depositing said transition metal on said β-Ga₂O₃ or β-Ga₂O₃ alloy substrate and heating said β-Ga₂O₃ or β-Ga₂O₃ alloy substrate with said transition metal thereon.

11. The method of any of the examples above, wherein said transition metal comprises copper.

12. The method of any of the examples above, wherein said transition metal comprises silver or molybdenum.

13. The method of any of the examples above, further comprising doping said β-Ga₂O₃ or β-Ga₂O₃ alloy substrate with an additional different dopant.

14. The method of Example 13, wherein said additional different dopant comprises Si, Ge, or Sn.

15. The method of any of the examples above, further comprising configuring said optically addressable light valve to apply voltage across said liquid crystal.

16. The method of any of Examples 1-15, wherein providing a substrate of β-Ga₂O₃ or β-Ga₂O₃ alloy comprises providing a β-Ga₂O₃ substrate.

17. The method of any of Examples 1-15, wherein providing a substrate of β-Ga₂O₃ or β-Ga₂O₃ alloy comprises providing a substrate of a β-Ga₂O₃ alloy.

18. The method of Example 17, wherein said β-Ga₂O₃ alloy comprises an alloy with aluminum or indium.

19. The method of Example 18, wherein said β-Ga₂O₃ alloy comprises GaₓIn_{y}O₃ (Gallium Indium Oxide).

20. The method of Example 18, wherein said β-Ga₂O₃ alloy comprises AlₓGa_{y}O₃ (Aluminum Gallium Oxide).

### Examples—Part IV

1. A method of forming a photoconductive semiconductor switch configured to optically modulate electricity, said method comprising:
providing a substrate of β-Ga₂O₃ or β-Ga₂O₃ alloy thereof;
diffusing a transition metal into said β-Ga₂O₃ or β-Ga₂O₃ alloy substrate;
providing a first conductor on one side of said β-Ga₂O₃ or β-Ga₂O₃ alloy substrate, said first conductor layer being optically transmissive; and
providing a second conductor layer on an opposite side of said β-Ga₂O₃ or β-Ga₂O₃ alloy substrate as said first conductor layer.

2. The method of Example 1, wherein said transition metal is diffused into said β-Ga₂O₃ or β-Ga₂O₃ alloy substrate no more than 100 micrometers.

3. The method of Example 2, wherein said transition metal is diffused into said β-Ga₂O₃ or β-Ga₂O₃ alloy substrate at least 50 micrometers.

4. The method of Example 1, wherein said transition metal is diffused into said β-Ga₂O₃ or β-Ga₂O₃ alloy substrate no more than 50 micrometers.

5. The method of Example 4, wherein said transition metal is diffused into said β-Ga₂O₃ or β-Ga₂O₃ alloy substrate at least 30 micrometers.

6. The method of Example 1, wherein said transition metal is diffused into said β-Ga₂O₃ or β-Ga₂O₃ alloy substrate no more than 20 micrometers.

7. The method of Example 6, wherein said transition metal is diffused into said β-Ga₂O₃ or β-Ga₂O₃ alloy substrate at least 10 micrometers.

8. The method of Example 1, wherein said transition metal is diffused into said β-Ga₂O₃ or β-Ga₂O₃ alloy substrate no more than 10 micrometers.

9. The method of Example 8, wherein said transition metal is diffused into said β-Ga₂O₃ or β-Ga₂O₃ alloy substrate at least 5 micrometers.

10. The method of any of the examples above, wherein said transition metal is diffused into said β-Ga₂O₃ or β-Ga₂O₃ alloy substrate by depositing said transition metal on said β-Ga₂O₃ or β-Ga₂O₃ alloy substrate and heating said β-Ga₂O₃ or β-Ga₂O₃ alloy substrate with said transition metal thereon.

11. The method of any of the examples above, wherein said transition metal comprises copper.

12. The method of any of the examples above, wherein said transition metal comprises silver or molybdenum.

13. The method of any of the examples above, further comprising doping said β-Ga₂O₃ or β-Ga₂O₃ alloy substrate with an additional different dopant.

14. The method of Example 13, wherein said additional different dopant comprises Si, Ge, or Sn.

15. The method of any of the examples above, further comprising configuring said photoconductive semiconductor switch to apply voltage across at least a portion of said β-Ga₂O₃ or β-Ga₂O₃ alloy substrate having transition metal diffused therein.

16. The method of any of Examples 1-15, wherein providing a substrate of β-Ga₂O₃ or β-Ga₂O₃ alloy comprises providing a β-Ga₂O₃ substrate.

17. The method of any of Examples 1-15, wherein providing a substrate of β-Ga₂O₃ or β-Ga₂O₃ alloy comprise providing a substrate of a β-Ga₂O₃ alloy.

18. The method of Example 17, wherein said β-Ga₂O₃ alloy comprises an alloy with aluminum or indium.

19. The method of Example 18, wherein said β-Ga₂O₃ alloy comprises GaₓIn_{y}O₃ (Gallium Indium Oxide).

20. The method of Example 18, wherein said β-Ga₂O₃ alloy comprises AlₓGa_{y}O₃ (Aluminum Gallium Oxide).

### Examples—Part V

1. An optical device comprising:
a layer of β-Ga₂O₃ or alloy thereof including a region doped with transition metal, said region (a) having a thickness of no more than 100 micrometers, (b) having
a gradient in concentration of said transition metal that decrease from an edge of said layer of β-Ga₂O₃ or alloy thereof or (c) both; and
electronics configured to apply electricity to said layer of β-Ga₂O₃ or alloy thereof.

2. The optical device of Example 1, wherein said transition metal doped region has a thickness of no more than 100 micrometers.

3. The optical device of Example 2, wherein said transition metal doped region has a thickness of at least 50 micrometers.

4. The optical device of Example 1, wherein said transition metal doped region has a thickness of no more than 50 micrometers.

5. The optical device of Example 4, wherein said transition metal doped region has a thickness of at least 20 micrometers.

6. The optical device of Example 1, wherein said transition metal doped region has a thickness of no more than 20 micrometers.

7. The optical device of Example 6, wherein said transition metal doped region has a thickness of at least 10 micrometers.

8. The optical device of Example 1, wherein said transition metal doped region has a thickness of no more than 10 micrometers.

9. The optical device of Example 8, wherein said transition metal doped region has a thickness of at least 5 micrometers.

10. The optical device of any of the examples above, wherein said transition metal doped region has a gradient in concentration of said transition metal that decreases from an edge of said layer of β-Ga₂O₃ or alloy thereof.

11. The optical device of Example 10, wherein said gradient in concentration of said transition metal decreases in a manner consistent with diffusing said transition metal into said layer of β-Ga₂O₃ or alloy thereof.

12. The optical device of Example 10 or 11, wherein said gradient in concentration of said transition metal follows a gaussian or complementary error function falloff.

13. The optical device of any of the examples above, wherein said transition metal comprises copper.

14. The optical device of any of the examples above, wherein said transition metal comprises silver or molybdenum.

15. The optical device of any of the examples above, wherein said layer of β-Ga₂O₃ or alloy thereof further comprises an additional different dopant than said transition metal.

16. The optical device of Example 15, wherein said additional different dopant is selected from Si, Ge, or Sn.

17. The optical device of any of the examples above, further comprising first and second electrical conductors on opposite sides of said layer of β-Ga₂O₃ to apply a voltage across said layer of β-Ga₂O₃ or alloy thereof.

18. The optical device of Example 17, wherein said first conductor is formed in said layer of β-Ga₂O₃ or alloy thereof on one side such that said first conductor and said layer of β-Ga₂O₃ or alloy thereof comprise a single monolithic structure.

19. The optical device of any of Examples 17 or 18, wherein said layer of β-Ga₂O₃ includes a sufficiently high amount of impurity dopants on a side of said layer of β-Ga₂O₃ opposite said first conductor to form said second conductor, said second conductor disposed in said layer of β-Ga₂O₃ or alloy thereof.

20. The optical device of Example 1-9 and 13-19, wherein said layer of β-Ga₂O₃ or alloy thereof is epitaxially grown with said transition metal in said transition metal doped region.

21. The optical device of any the examples above, wherein said optical device is configured to apply a voltage across said region doped with transition metal in said layer of 3-Ga₂O₃ or alloy thereof.

22. The optical device of any of the examples above, wherein said transition metal dopants cause the region doped with transition metal in said layer of β-Ga₂O₃ or alloy thereof to generate photocarriers in response to receiving visible light or ultraviolet light having a wavelength of at least 350 nm.

23. The optical device of any of the examples above, wherein at least one of said first and second conductors is optically transmissive to a wavelength of visible or ultraviolet light.

24. An optical device comprising: a layer of β-Ga₂O₃ or alloy thereof including a doped region with a transition metal diffused therein, and electronics configured to apply electricity to said layer of β-Ga₂O₃ or alloy thereof.

25. The optical device of Example 24, wherein said transition metal doped region has a thickness of no more than 100 micrometers.

26. The optical device of Example 25, wherein said transition metal doped region has a thickness of at least 50 micrometers.

27. The optical device of Example 24, wherein said transition metal doped region has a thickness of no more than 50 micrometers.

28. The optical device of Example 27, wherein said transition metal doped region has a thickness of at least 20 micrometers.

29. The optical device of Example 24, wherein said transition metal doped region has a thickness of no more than 20 micrometers.

30. The optical device of Example 29, wherein said transition metal doped region has a thickness of at least 10 micrometers.

31. The optical device of Example 24, wherein said transition metal doped region has a thickness of no more than 10 micrometers.

32. The optical device of Example 31, wherein said transition metal doped region has a thickness of at least 5 micrometers.

33. The optical device of any of Examples 24-32, wherein said transition metal doped region has a gradient in concentration of said transition metal that decreases from an edge of said layer of β-Ga₂O₃ or alloy thereof.

34. The optical device of Example 33, wherein said gradient in concentration of said transition metal decreases in a manner consistent with diffusing said transition metal into said layer of β-Ga₂O₃ or alloy thereof.

35. The optical device of Example 33 or 34, wherein said gradient in concentration of said transition metal follows a gaussian or complementary error function falloff.

36. The optical device of any of Examples 24-35, wherein said transition metal comprises copper.

37. The optical device of any of Examples 24-35, wherein said transition metal comprises silver or molybdenum.

38. The optical device of any of Examples 24-37, wherein said layer of β-Ga₂O₃ or alloy thereof further comprises an additional different dopant than said transition metal.

39. The optical device of Example 38, wherein said additional different dopant comprises Si, Ge, or Sn.

40. The optical device of any of Examples 24-39, further comprising first and second electrical conductors on opposite sides of said layer of β-Ga₂O₃ to apply a voltage across said layer of β-Ga₂O₃ or alloy thereof.

41. The optical device of Example 40, wherein said first conductor is formed in said layer of β-Ga₂O₃ or alloy thereof on one side such that said first conductor and said layer of β-Ga₂O₃ or alloy thereof comprise a single monolithic structure.

42. The optical device of any of Examples 40 or 41, wherein said layer of β-Ga₂O₃ or alloy thereof includes a sufficiently high amount of impurity dopants on a side of said layer of β-Ga₂O₃ or alloy thereof opposite said first conductor to form said second conductor, said second conductor disposed in said layer of β-Ga₂O₃ or alloy thereof.

43. The optical device of Examples 24-32 and 36-42, wherein said layer of β-Ga₂O₃ or alloy thereof is epitaxially grown with said transition metal in said transition metal doped region.

44. The optical device of any Examples 24-43, wherein said optical device is configured to apply a voltage across said region doped with transition metal in said layer of β-Ga₂O₃ or alloy thereof.

45. The optical device of any Examples 24-44, wherein said transition metal dopants cause the region doped with transition metal in said layer of j-Ga₂O₃ or alloy thereof to generate photocarriers in response to receiving visible light or ultraviolet light having a wavelength of at least 350 nm.

46. The optical device of any Examples 24-45, wherein at least one of said first and second conductors is optically transmissive to a wavelength of visible or ultraviolet light.

47. The optical device of any of Examples 1-46, wherein said layer of β-Ga₂O₃ or alloy thereof comprises a layer of β-Ga₂O₃.

48. The optical device of any of Examples 1-46, wherein said layer of β-Ga₂O₃ or alloy thereof comprises a layer of a j-Ga₂O₃ alloy.

49. The optical device of Example 48, wherein said layer of j-Ga₂O₃ alloy comprises an alloy with aluminum or indium.

50. The optical device of Example 49, wherein said layer of j-Ga₂O₃ alloy comprises GaₓIn_{y}O₃ (Gallium Indium Oxide).

51. The optical device of Example 49, wherein said layer of j-Ga₂O₃ alloy comprises AlₓGa_{y}O₃ (Aluminum Gallium Oxide).

52. The optical device of any of Examples 1-51, wherein said optical device comprise a photoconductive semiconductor switch.

53. The optical device of any of Examples 1-51, wherein said optical device comprise a optically addressable light valve.

### Examples—Part VI

1. A method of forming an optical device, said method comprising:
providing a layer of j-Ga₂O₃ or alloy thereof;
diffusing a transition metal into a layer of j-Ga₂O₃ or alloy thereof, and
configuring said optical device to apply electricity to at least a portion of said layer of β-Ga₂O₃ or alloy thereof having said transition metal diffused therein.

2. The method of Example 1, wherein said transition metal is diffused into said β-Ga₂O₃ or alloy thereof substrate no more than 100 micrometers.

3. The method of Example 2, wherein said transition metal is diffused into said β-Ga₂O₃ or alloy thereof substrate at least 50 micrometers.

4. The method of Example 1, wherein said transition metal is diffused into said β-Ga₂O₃ or alloy thereof substrate no more than 50 micrometers.

5. The method of Example 4, wherein said transition metal is diffused into said β-Ga₂O₃ or alloy thereof substrate at least 30 micrometers.

6. The method of Example 1, wherein said transition metal is diffused into said β-Ga₂O₃ or alloy thereof substrate no more than 20 micrometers.

7. The method of Example 6, wherein said transition metal is diffused into said β-Ga₂O₃ or alloy thereof substrate at least 10 micrometers.

8. The method of Example 1, wherein said transition metal is diffused into said β-Ga₂O₃ or alloy thereof substrate no more than 10 micrometers.

9. The method of Example 8, wherein said transition metal is diffused into said β-Ga₂O₃ or alloy thereof substrate at least 5 micrometers.

10. The method of any of the examples above, wherein said transition metal is diffused into said layer of β-Ga₂O₃ or alloy thereof by depositing said transition metal on said layer of β-Ga₂O₃ or alloy thereof and heating said layer of β-Ga₂O₃ or alloy thereof with said transition metal thereon.

11. The method of any of the examples above, wherein said transition metal comprises copper.

12. The method of any of the examples above, wherein said transition metal comprises silver or molybdenum.

13. The method of any of the examples above, further comprising doping said layer of β-Ga₂O₃ or alloy thereof with an additional different dopant.

14. The method of Example 13, wherein said additional different dopant comprises Si, Ge, or Sn.

15. The method of any of the examples above, further comprising configuring said device to apply voltage across said layer of β-Ga₂O₃ or alloy thereof.

16. The method of any of the examples above, wherein said layer of β-Ga₂O₃ or alloy thereof comprises a substrate of β-Ga₂O₃ or alloy thereof.

17. The method of any of Examples 1-16, wherein providing a layer of β-Ga₂O₃ or alloy thereof comprises providing a β-Ga₂O₃ substrate.

18. The method of any of Examples 1-16, wherein providing a layer of β-Ga₂O₃ or alloy thereof comprise providing a substrate of a β-Ga₂O₃ alloy.

19. The method of Example 18, wherein said β-Ga₂O₃ alloy comprises an alloy with aluminum or indium.

20. The method of Example 19, wherein said β-Ga₂O₃ alloy comprises GaₓIn_{y}O₃ (Gallium Indium Oxide).

21. The method of Example 19, wherein said β-Ga₂O₃ alloy comprises AlₓGa_{y}O₃ (Aluminum Gallium Oxide).

22. The method of any of Examples 1-21, wherein said optical device comprise a photoconductive semiconductor switch.

23. The method of any of Examples 1-21, wherein said optical device comprise a optically addressable light valve.

### Examples—Part VII

1. A photoconductive β-Ga₂O₃ device whereby a photoconductive layer is integrated into a bulk doped n-type β-Ga₂O₃ wafer or chip with controlled thickness.

2. A device where the photoconductor layer in Example 1 is created by doping with a transition metal.

3. A device where the photoconductor layer in Example 1 is created by co-doping with a donor and a transition metal.

4. A device where the photoconductor layer in Example 1 is formed by diffusion of a transition metal into an n-type β-Ga₂O₃ substrate.

5. A device where the photoconductor layer in Example 1 is formed by diffusion of a transition metal and a donor into an n-type β-Ga₂O₃ substrate.

6. A device where the photoconductor layer in Example 1 is formed by epitaxial growth of a β-Ga₂O₃ layer doped with a transition metal.

7. A device where the photoconductor layer in Example 1 is formed by epitaxial growth of a β-Ga₂O₃ layer doped with a transition metal and a donor.

8. A device in Example 1 where the device is a photo-triggered photoconductive semiconductor switch.

9. A device in Example 1 where the device is the photoconductive component of an optically addressable light valve.

10. A device in Example 1 where a transparent conductor is placed on the photoconductive layer by deposition of a transparent conducting oxide or an n-type epitaxial β-Ga₂O₃ layer.

### Examples—Part VIII

1. A photoconductive semiconductor device, said photoconductive semiconductor device comprising:
a first conductor;
a layer of β-Ga₂O₃ or alloy thereof, said layer of β-Ga₂O₃ or alloy thereof including a region doped with transition metal, said doped region (a) having a thickness of no more than 100 micrometers, (b) having a gradient in concentration of said transition metal that decreases from an edge of said layer of β-Ga₂O₃ or alloy thereof, or (c) both; and
a second conductor, said second conductor on the opposite side of said layer of β-Ga₂O₃ or alloy thereof than said first conductor,
wherein at least one of said first and second conductor is optically transmissive.

2. The photoconductive semiconductor device of Example 1, wherein said transition metal doped region has a thickness of no more than 100 micrometers.

3. The photoconductive semiconductor device of Example 2, wherein said transition metal doped region has a thickness of at least 50 micrometers.

4. The photoconductive semiconductor device of Example 1, wherein said transition metal doped region has a thickness of no more than 50 micrometers.

5. The photoconductive semiconductor device of Example 1, wherein said transition metal doped region has a gradient in concentration of said transition metal that decreases from an edge of said layer of β-Ga₂O₃ or alloy thereof.

6. The photoconductive semiconductor device of Example 1, wherein said transition metal comprises copper.

7. A photoconductive semiconductor device comprising:
a first conductor;
a layer of β-Ga₂O₃ or alloy thereof; and
a second conductor, said second conductor on an opposite side of said layer of β-Ga₂O₃ or alloy thereof than said first conductor,
wherein said layer of β-Ga₂O₃ or alloy thereof includes a doped region with a transition metal diffused therein, and
wherein at least one of said first and second conductors is optically transmissive.

8. The photoconductive semiconductor device of Example 7, wherein said doped region has a thickness of no more than 100 micrometers.

9. The photoconductive semiconductor device of Example 8, wherein said doped region has a thickness of at least 50 micrometers.

10. The photoconductive semiconductor device of Example 7, wherein said doped region has a thickness of no more than 50 micrometers.

11. The photoconductive semiconductor device of Example 7, wherein said doped region has a gradient in concentration of said transition metal that decreases from an edge of said layer of β-Ga₂O₃ or alloy thereof.

12. The photoconductive semiconductor device of Example 7, wherein said transition metal comprises copper.

13. A method of forming a photoconductive semiconductor device, said method comprising:
providing a substrate of β-Ga₂O₃ or alloy thereof;
diffusing a transition metal into said β-Ga₂O₃ or β-Ga₂O₃ alloy substrate;
providing a first conductor on one side of said β-Ga₂O₃ or β-Ga₂O₃ alloy substrate, said first conductor layer being optically transmissive; and
providing a second conductor layer on an opposite side of said β-Ga₂O₃ or β-Ga₂O₃ alloy substrate as said first conductor layer.

14. The method of Example 13, wherein said transition metal is diffused into said β-Ga₂O₃ or β-Ga₂O₃ alloy substrate by depositing said transition metal on said β-Ga₂O₃ or β-Ga₂O₃ alloy substrate and heating said β-Ga₂O₃ or β-Ga₂O₃ alloy substrate with said transition metal thereon.

15. The method of Example 13, wherein providing a substrate of β-Ga₂O₃ or alloy thereof comprises providing a β-Ga₂O₃ substrate.

16. The method of Example 13, wherein providing a substrate of β-Ga₂O₃ or alloy thereof alloy comprise providing a substrate of a β-Ga₂O₃ alloy.

17. The photoconductive semiconductor device of Example 1, wherein said layer of β-Ga₂O₃ or alloy thereof comprises a layer of β-Ga₂O₃.

18. The photoconductive semiconductor device of Example 1, wherein said layer of β-Ga₂O₃ or alloy thereof comprises a layer of a β-Ga₂O₃ alloy.

19. The photoconductive semiconductor device of Example 7, wherein said layer of β-Ga₂O₃ or alloy thereof comprises a layer of β-Ga₂O₃.

20. The photoconductive semiconductor device of Example 7, wherein said layer of β-Ga₂O₃ or alloy thereof comprises a layer of a β-Ga₂O₃ alloy.

Although the description above contains many details and specifics, these should not be construed as limiting the scope of the invention but as merely providing illustrations of some of the presently preferred embodiments of this invention. Other implementations, enhancements and variations can be made based on what is described and illustrated in this patent document. The features of the embodiments described herein may be combined in all possible combinations of methods, apparatus, modules, systems, and computer program products. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially Exampled as such, one or more features from a claimed combination can in some cases be excised from the combination, and the claimed combination may be directed to a subcombination or variation of a subcombination. Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described above should not be understood as requiring such separation in all embodiments.

Therefore, it will be appreciated that the scope of the present invention fully encompasses other embodiments which may become obvious to those skilled in the art. In the Examples, reference to an element in the singular is not intended to mean “one and only one” unless explicitly so stated, but rather “one or more.” All structural and functional equivalents to the elements of the above-described preferred embodiment that are known to those of ordinary skill in the art are expressly incorporated herein by reference and are intended to be encompassed by the present Examples. Moreover, it is not necessary for a device to address each and every problem sought to be solved by the present invention, for it to be encompassed by the present Examples. Furthermore, no element or component in the present disclosure is intended to be dedicated to the public regardless of whether the element or component is explicitly recited in the Examples. No Example element herein is to be construed under the provisions of 35 U.S.C. 112, sixth paragraph, unless the element is expressly recited using the phrase “means for.”

What is claimed is:

1. A photoconductive semiconductor device, said photoconductive semiconductor device comprising:
a first conductor;
a layer of β-Ga₂O₃ or alloy thereof, said layer of β-Ga₂O₃ or alloy thereof including a region doped with transition metal, said doped region (a) having a thickness of no more than 100 micrometers, (b) having a gradient in concentration of said transition metal that decreases from an edge of said layer of β-Ga₂O₃ or alloy thereof, or (c) both; and
a second conductor, said second conductor on the opposite side of said layer of β-Ga₂O₃ or alloy thereof than said first conductor,
wherein at least one of said first and second conductor is optically transmissive.

2. The photoconductive semiconductor device of claim 1, wherein said transition metal doped region has a thickness of no more than 100 micrometers.

3. The photoconductive semiconductor device of claim 2, wherein said transition metal doped region has a thickness of at least 50 micrometers.

4. The photoconductive semiconductor device of claim 1, wherein said transition metal doped region has a thickness of no more than 50 micrometers.

5. The photoconductive semiconductor device of claim 1, wherein said transition metal doped region has a gradient in concentration of said transition metal that decreases from an edge of said layer of β-Ga₂O₃ or alloy thereof.

6. The photoconductive semiconductor device of claim 1, wherein said transition metal comprises copper.

7. A photoconductive semiconductor device comprising:
a first conductor;
a layer of β-Ga₂O₃ or alloy thereof; and
a second conductor, said second conductor on an opposite side of said layer of β-Ga₂O₃ or alloy thereof than said first conductor,
wherein said layer of β-Ga₂O₃ or alloy thereof includes a doped region with a transition metal diffused therein, and
wherein at least one of said first and second conductors is optically transmissive.

8. The photoconductive semiconductor device of claim 7, wherein said doped region has a thickness of no more than 100 micrometers.

9. The photoconductive semiconductor device of claim 8, wherein said doped region has a thickness of at least 50 micrometers.

10. The photoconductive semiconductor device of claim 7, wherein said doped region has a thickness of no more than 50 micrometers.

11. The photoconductive semiconductor device of claim 7, wherein said doped region has a gradient in concentration of said transition metal that decreases from an edge of said layer of β-Ga₂O₃ or alloy thereof.

12. The photoconductive semiconductor device of claim 7, wherein said transition metal comprises copper.

1. A method of forming a photoconductive semiconductor device, said method comprising:
providing a substrate of β-Ga₂O₃ or alloy thereof;
diffusing a transition metal into said β-Ga₂O₃ or β-Ga₂O₃ alloy substrate;
providing a first conductor on one side of said β-Ga₂O₃ or β-Ga₂O₃ alloy substrate, said first conductor layer being optically transmissive; and
providing a second conductor layer on an opposite side of said β-Ga₂O₃ or β-Ga₂O₃ alloy substrate as said first conductor layer.

1. The method of claim 13, wherein said transition metal is diffused into said β-Ga₂O₃ or β-Ga₂O₃ alloy substrate by depositing said transition metal on said β-Ga₂O₃ or β-Ga₂O₃ alloy substrate and heating said β-Ga₂O₃ or β-Ga₂O₃ alloy substrate with said transition metal thereon.

2. The method of claim 13, wherein providing a substrate of β-Ga₂O₃ or alloy thereof comprises providing a β-Ga₂O₃ substrate.

3. The method of claim 13, wherein providing a substrate of β-Ga₂O₃ or alloy thereof alloy comprise providing a substrate of a β-Ga₂O₃ alloy.

4. The photoconductive semiconductor device of claim 1, wherein said layer of β-Ga₂O₃ or alloy thereof comprises a layer of β-Ga₂O₃.

5. The photoconductive semiconductor device of claim 1, wherein said layer of 3-Ga₂O₃ or alloy thereof comprises a layer of a β-Ga₂O₃ alloy.

6. The photoconductive semiconductor device of claim 7, wherein said layer of β-Ga₂O₃ or alloy thereof comprises a layer of β-Ga₂O₃.

7. The photoconductive semiconductor device of claim 7, wherein said layer of β-Ga₂O₃ or alloy thereof comprises a layer of a β-Ga₂O₃ alloy.
